(19) United States
(12) Patent Application Publication
(10) Pub. No.: US 2025/0176089 A1
(43) Pub. Date: May 29, 2025

(54) LIGHT SOURCE APPARATUS AND OPTICAL APPARATUS

(71) Applicant: Lasertec Corporation, Kanagawa (JP)

(72) Inventors: Masaki Inoue, Kanagawa (JP); Masayasu Nishizawa, Kanagawa (JP)

(73) Assignee: Lasertec Corporation, Kanagawa (JP)

(21) Appl. No.: 18/941,268

(22) Filed: Nov. 8, 2024

(30) Foreign Application Priority Data
Nov. 27, 2023 (JP) 2023-199600

(51) Int. Cl. H05G 2/00

(52) U.S. Cl. CPC H05G 2/002; H05G 2/0035; H05G 2/0092

(57) ABSTRACT

A light source apparatus according to the present embodiment includes: a target holding unit including a holding region configured to hold a target material that generates light by excitation light being provided; a rotary shaft configured to support the target holding unit; and an axial rotation drive unit that is connected to the rotary shaft and configured to rotate, the target holding unit around a central axis of the rotary shaft, wherein the target holding unit is rotated by a predetermined target rotational angular velocity, and the target holding unit has a mass such that a critical angular velocity during rotation is equal to or lower than 85% of the target rotational angular velocity.

### INCORPORATION BY REFERENCE

This application is based upon and claims the benefit of priority from Japanese patent application No. 2023-199600, filed on Nov. 27, 2023, the disclosure of which is incorporated herein in its entirety by reference.

### BACKGROUND

The present disclosure relates to a light source apparatus and an optical apparatus.

Patent Literature 1 describes a light source that forms a target material on a surface of a cylindrical member rotating around a rotational axis and obtains luminescence by irradiating the target material with excitation light.

Patent Literature 2 describes a light source that centrifugally holds a target material of molten metal on an inner wall of a crucible rotating around a rotational axis and obtains luminescence by irradiating the target material with excitation light.
Patent Literature 1: Japanese Unexamined Patent Application Publication No. 2020-077007
Patent Literature 2: Japanese Unexamined Patent Application Publication No. 2022-168463

### SUMMARY

There may be cases where vibration generated during a rotation of a structure changes a target irradiation position and prevents light from being stably extracted.

An object of the present disclosure, which has been made in consideration of such a problem, is to provide a light source apparatus and an optical apparatus that enable stability of light generated from a light source to be improved.

A light source apparatus according to an aspect of the present embodiment includes: a target holding unit including a holding region configured to hold a target material that generates light by excitation light being provided; a rotary shaft configured to support the target holding unit; and an axial rotation drive unit that is connected to the rotary shaft and configured to rotate the target holding unit around a central axis of the rotary shaft, in which the target holding unit is rotated by a predetermined target rotational angular velocity, and the target holding unit has a mass such that a critical angular velocity during rotation is equal to or lower than 85% of the target rotational angular velocity.

In the light source apparatus described above, the target holding unit may include the holding region and a weight unit, and when one orientation in a direction of the central axis is considered one side and an orientation on an opposite side to the one side is considered another side, the holding region may be arranged on the one side of the weight unit and the weight unit may extend on the other side.

A light source apparatus according to an aspect of the present embodiment includes: a target holding unit including a holding region configured to hold a target material that generates light by excitation light being provided; a rotary shaft configured to support the target holding unit; and an axial rotation drive unit that is connected to the rotary shaft and configured to rotate the target holding unit around a central axis of the rotary shaft, in which the target holding unit includes the holding region and a weight unit, and when one orientation in a direction of the central axis is considered one side and an orientation on an opposite side to the one side is considered another side, the holding region is arranged on the one side of the weight unit and the weight unit extends on the other side.

In the light source apparatus described above, the target holding unit may include: a conveying unit configured to hold the target material with the holding region and convey the target material to an irradiation position; and a weight unit joined to the rotary shaft, in which the conveying unit is detachable from the weight unit and is attached to the weight unit when the excitation light is provided to the target material.

In the light source apparatus described above, a temperature during a step of fitting the rotary shaft into the weight unit may be lower than a temperature of the rotary shaft and the weight unit when providing the target material with the excitation light and, at the same time, a coefficient of linear expansion of the weight unit may be smaller than the coefficient of linear expansion of the rotary shaft, or a temperature during the step of fitting the rotary shaft into the weight unit may be higher than a temperature of the rotary shaft and the weight unit when providing the target material with the excitation light and, at the same time, a coefficient of linear expansion of the weight unit may be larger than the coefficient of linear expansion of the rotary shaft.

In the light source apparatus described above, the target material may be molten tin and, at the same time, a coefficient of linear expansion of the weight unit may be smaller than the coefficient of linear expansion of the rotary shaft, or the target material may be frozen xenon and, at the same time, a coefficient of linear expansion of the weight unit may be larger than the coefficient of linear expansion of the rotary shaft.

In the light source apparatus described above, the weight unit may be joined to the rotary shaft by welding.

In the light source apparatus described above, the weight unit may be fastened by a bolt to a flange provided on the rotary shaft.

In the light source apparatus described above, the target material may be molten metal, and the conveying unit may be configured to hold the target material with a centrifugal force created by a rotation around the central axis and convey the target material to the irradiation position.

In the light source apparatus described above, the target holding unit may further include a joining member configured to join the conveying unit and the weight unit, in which the joining member may be attached from the conveying unit toward the weight unit, the conveying unit may rotate together with the weight unit when joined to the weight unit by the joining member, and the conveying unit may be detachable from the rotary shaft when not joined by the joining member.

In the light source apparatus described above, the weight unit may include a hole-shaped balance hole configured to adjust a balance of mass of the weight unit, and the conveying unit may be attached to the weight unit after passing a test in a state where the conveying unit is not attached to the weight unit.

The light source apparatus described above may further include a refill unit configured to refill the conveying unit with the molten metal so that a predetermined amount of the target material is held by the conveying unit, and a mass of the weight unit may be determined based on the mass of the conveying unit and the mass of the predetermined amount of the molten metal.

The light source apparatus described above may further include: a vacuum chamber in which the conveying unit is arranged; a weight casing in which at least a part of the weight unit is arranged; and a cooling unit that is arranged between the conveying unit and the weight unit and configured to cool the target holding unit.

The light source apparatus described above may further include: an introduction port that is formed in the cooling unit and configured to introduce cooling gas toward a space between the cooling unit and the conveying unit; and an exhaust port that is formed in the weight casing and configured to exhaust the cooling gas.

An inspection apparatus according to an aspect of the present embodiment includes the light source apparatus described above and performs lithography or an inspection based on light generated from the target material.

According to the present disclosure, a light source apparatus and an optical apparatus that enable stability of light generated from a light source to be improved can be provided.

The above and other objects, features and advantages of the present disclosure will become more fully understood from the detailed description given hereinbelow and the accompanying drawings.

### BRIEF DESCRIPTION OF DRAWINGS

FIG. 1 is a sectional view illustrating a light source apparatus according to a first embodiment;

FIG. 2 is a graph illustrating an amount of whirling from a central axis when a target holding unit rotates around the central axis in the light source apparatus according to the first embodiment, in which an axis of abscissa indicates a frequency of rotation of the target holding unit and an axis of ordinate indicates the amount of whirling;

FIG. 3 is a configuration diagram illustrating an inspection apparatus including the light source apparatus according to the first embodiment; and

FIG. 4 is a sectional view illustrating a light source apparatus according to a second embodiment.

### DESCRIPTION OF EMBODIMENTS

Hereinafter, embodiments of the present disclosure will be described with reference to the drawings. The following description is intended as a description of preferred embodiments of the present disclosure and is not intended to limit the scope of the present disclosure to the following embodiments. In the following description, same reference signs denote substantially similar content.

### First Embodiment

A light source apparatus according to a first embodiment will be described. The light source apparatus according to the present embodiment generates light such as illumination light or exposure light used in an optical apparatus such as an inspection apparatus or an exposure apparatus. The light source apparatus may be provided integrally with the optical apparatus or arranged in a vicinity of the optical apparatus as a separate body from the optical apparatus. When the optical apparatus is an inspection apparatus, the light source apparatus generates illumination light that illuminates an inspection object in the inspection apparatus. Alternatively, when the optical apparatus is an exposure apparatus, the light source apparatus generates exposure light that exposes an exposure object in the exposure apparatus.

The light source apparatus generates light such as illumination light or exposure light by irradiating a target material held by a target holding unit with excitation light. Therefore, the optical apparatus performs lithography or an inspection based on light generated from the target material. Hereinafter, an example of using molten metal held in a container as a target material will be described as an example of the light source apparatus. Note that the light source apparatus is not limited to using molten metal held in a container as the target material and may use liquid metal with a droplet shape, solid material fixed to a cylinder-shaped drum, or the like as the target material.

### <Light Source Apparatus>

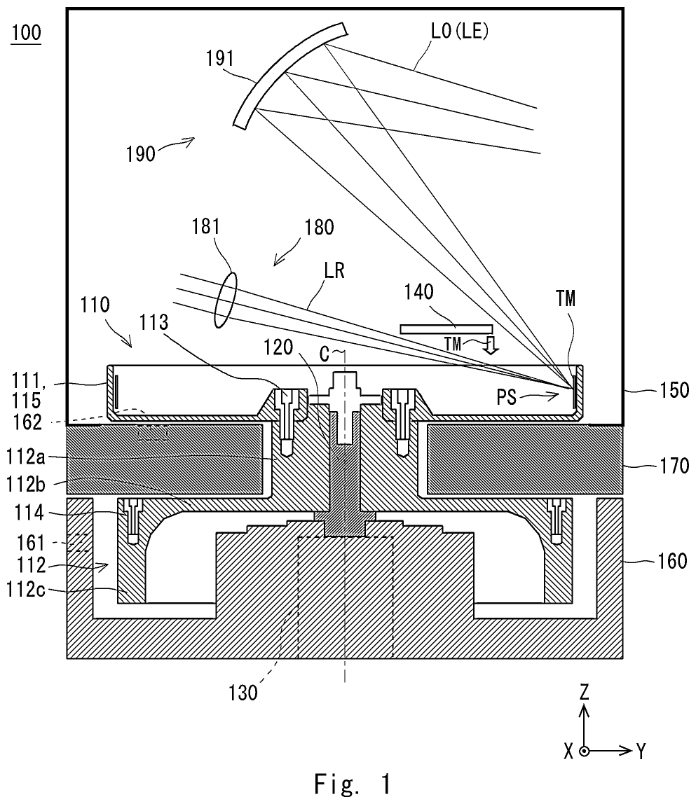

FIG. 1 is a sectional view illustrating a light source apparatus 100 according to the first embodiment. In FIG. 1, hatchings of some members have been omitted to avoid complicating the drawing. As shown in FIG. 1, the light source apparatus 100 includes a target holding unit 110, a rotary shaft 120, and an axial rotation drive unit 130. The light source apparatus 100 may further include a refill unit 140, a vacuum chamber 150, a weight casing 160, an exhaust port 161, a cooling unit 170, an input optical system 180, and an output optical system 190. Note that the light source apparatus 100 may include a drive member, a storage member, an optical member, and the like other than those described above or some members among the drive members, storage members, optical members, and the like described above may be omitted.

The target holding unit 110 holds a target material TM that generates light L0 when excitation light LR is provided. The target holding unit 110 includes a holding region that holds the target material TM. The target holding unit 110 includes a conveying unit 111 and a weight unit 112. The conveying unit 111 holds the target material TM and conveys the target material TM to an irradiation position PS of the excitation light LR. For example, the conveying unit 111 includes a container 115 such as a crucible. Note that the conveying unit 111 is not limited to including the container 115 as long as the target material TM can be conveyed to the irradiation position PS of the excitation light LR and may include a drum. The container 115 is capable of internally melting metal. The container 115 can hold the target material TM such as molten metal that generates plasma when being irradiated with the excitation light LR. For example, the excitation light LR is laser light including IR (Infrared) light.

The target material TM may include molten metal. The target material TM is not limited to molten metal held in the container 115 and may be a solid material, droplets, or the like as long as the target material TM is a substance that generates plasma when being irradiated with the excitation light LR. While examples of molten metal include molten tin (Sn) and molten lithium (Li), the molten metal is not limited to tin and lithium as long as the molten metal generates plasma when being irradiated with the excitation light LR.

The conveying unit 111 in the target holding unit 110 is not limited to including the container 115 and may include a cylindrical (cylinder-shaped) drum. In such a case, the target holding unit 110 holds the target material TM by fixing a solid material to be the target material TM such as xenon (Xe) having been frozen on a surface of the drum. A region of the surface of the drum to which the solid material is fixed in this manner may be considered a holding region that holds the target material TM.

For example, the container 115 is a cylindrical shape with one closed opening. A closed portion of the container 115 is referred to as a bottom part. A cylindrical portion of the container 115 is referred to as a cylindrical part. An inside surface of the bottom part is referred to as a bottom surface. An inside surface of the cylindrical part is referred to as an inner wall surface. The inner wall surface may be considered a holding region that holds the target material TM. Note that the container 115 may include a shape other than that described above as long as molten metal can be held.

For example, a hole is formed along a central axis in the target holding unit 110 or the target holding unit 110 is provided with a cavity along the central axis. The target holding unit 110 is joined to the rotary shaft 120 inside the hole (cavity). For example, the target holding unit 110 may be joined to the rotary shaft 120 via a bolt. Accordingly, the target holding unit 110 is supported by the rotary shaft 120. The target holding unit 110 rotates around a central axis C of the rotary shaft 120.

An XYZ orthogonal coordinate axes system will now be introduced for convenience of description of the light source apparatus 100. Let a direction along the central axis C of the rotary shaft 120 be a Z-axis direction and two directions orthogonal to the central axis C be an X-axis direction and a Y-axis direction. For example, a +Z-axis direction will be referred to as upward and a −Z-axis direction will be referred to as downward. In addition, the +Z-axis direction will sometimes be referred to as one side and the −Z-axis direction will sometimes be referred to as another side. Therefore, an orientation of one direction of the central axis C is the one side and an orientation of an opposite side to the one side is the other side. Note that upward and downward are directions for convenience of description of the light source apparatus 100 and do not indicate actual directions in which the light source apparatus 100 is arranged.

As described earlier, the target holding unit 110 includes the conveying unit 111 and the weight unit 112. The conveying unit 111 includes the holding region. Therefore, the target holding unit 110 includes the holding region and the weight unit 112. The holding region is arranged in the +Z-axis direction of the weight unit 112. The weight unit 112 extends in the −Z-axis direction. In this manner, the target holding unit 110 includes the weight unit 112 on a side of the −Z-axis direction of the conveying unit 111. The weight unit 112 includes a portion provided in the −Z-axis direction from a joining portion of the target holding unit 110 and the rotary shaft 120. The weight unit 112 may be provided on the side of the −Z-axis direction with respect to the joining portion of the target holding unit 110 and the rotary shaft 120. For example, the weight unit 112 may be provided closer to the axial rotation drive unit 130 than the joining portion of the target holding unit 110 and the rotary shaft 120. The weight unit 112 may include a portion which is farther away from the holding region than a joining portion of the target holding unit 112 and the rotary shaft 120. Each above example is an example where the weight unit 112 extends in the other side.

The conveying unit 111 is detachable from the weight unit 112. The conveying unit 111 is attached to the weight unit 112 when providing the target material TM with the excitation light LR. For example, the conveying unit 111 is attached to the weight unit 112 after passing a predetermined test in a state where the conveying unit 111 is not attached to the weight unit 112. For example, the predetermined test includes a test of balance of mass and a vibration test of the weight unit 112.

The target holding unit 110 may further include a joining member 113 that joins the conveying unit 111 and the weight unit 112 to each other. In addition, the conveying unit 111 may be joined to the weight unit 112 by the joining member 113. For example, the joining member 113 includes a bolt. For example, the joining member 113 may be attached from the conveying unit 111 toward the weight unit 112. Specifically, the joining member 113 may be attached from the bottom surface of the container 115 toward the weight unit 112.

Due to being joined to the weight unit 112 by the joining member 113, the conveying unit 111 rotates around the central axis C of the rotary shaft 120 together with the weight unit 112. When the conveying unit 111 is the container 115 and the target material TM is molten metal, the conveying unit 111 holds the target material TM with a centrifugal force created by rotation around the central axis C of the rotary shaft 120 and conveys the target material TM to the irradiation position PS. When the conveying unit 111 is not joined to the weight unit 112 by the joining member 113, the conveying unit 111 is detachable from the rotary shaft 120.

For example, the weight unit 112 may include, along the Z-axis direction, in order from above to below, a columnar portion 112a with a columnar shape, a disk portion 112b with a disk shape, and a cylindrical portion 112c with a cylindrical shape. Central axes of the columnar portion 112a, the disk portion 112b, and the cylindrical portion 112c coincide with each other. The columnar portion 112a, the disk portion 112b, and the cylindrical portion 112c may be integrated.

A diameter of the columnar portion 112a may be smaller than a diameter of the conveying unit 111. In addition, the diameter of the columnar portion 112a may be smaller than a diameter of the disk portion 112b. The diameter of the disk portion 112b may be the same as a diameter of the cylindrical portion 112c. A hole is formed along central axes of the columnar portion 112a and the disk portion 112b. The weight unit 112 is joined to the rotary shaft 120 inside the hole.

The columnar portion 112a is smaller than the diameter of the conveying unit 111 and the diameters of the disk portion 112b and the cylindrical portion 112c. The columnar portion 112a is arranged between the conveying unit 111 and a group made up of the disk portion 112b and the cylindrical portion 112c. In this manner, by arranging the conveying unit 111 having a larger diameter than the columnar portion 112a above the columnar portion 112a and arranging the disk portion 112b and the cylindrical portion 112c having a larger diameter than the columnar portion 112a below the columnar portion 112a, a balance in the Z-axis direction can be improved and a precession rotation and the like can be suppressed. Alternatively, a temperature regulating medium (for example, the cooling unit 170) may be arranged in a space outside of the columnar portion 112a (on a side away from the rotary shaft 120) and a layout that is more favorable in terms of temperature control of the target holding unit 110 can be realized.

The weight unit 112 may include a hole-shaped balance hole 114 for adjusting a balance of mass of the weight unit 112. The balance hole 114 is formed on a side of the −Z-axis direction from an upper surface on the side of the +Z-axis direction of the disk portion 112b and reaches the cylindrical portion 112c.

The weight unit 112 includes the hollow cylindrical portion 112c. Accordingly, a mass of a portion distanced from the rotary shaft 120 can be increased and an effect of balance adjustment due to the balance hole 114 can be enhanced. In addition, the cylindrical portion 112c may be arranged so as to enclose the axial rotation drive unit 130. For example, the cylindrical portion 112c may be arranged so as to enclose an axial rotation drive source such as a motor that is connected to the rotary shaft 120 as the axial rotation drive unit 130. In addition, the cylindrical portion 112c may be arranged so as to enclose a gear that is connected to the rotary shaft 120 as the axial rotation drive unit 130 (for example, a gear that transmits, to the rotary shaft 120, a drive force of a motor or the like connected to a rotary shaft that differs from the rotary shaft 120). Accordingly, the mass of the weight unit 112 can be increased without extending a length of the rotary shaft 120. As a result, an amount of whirling of the rotary shaft 120 can be suppressed and a balance of the target holding unit 110 can be improved.

The weight unit 112 may be joined to the rotary shaft 120 by shrink-fitting or cold fitting. Accordingly, the weight unit 112 is strongly joined to the rotary shaft 120. Preferably, members to be used as the weight unit 112 and the rotary shaft 120 are selected in accordance with a relationship between a temperature TO during a fitting step by shrink-fitting or cold fitting of the weight unit 112 to the rotary shaft 120 and a temperature T1 of the weight unit 112 and the rotary shaft 120 during an operating step of providing the target material with excitation light so that a coefficient of linear expansion of the weight unit 112 and a coefficient of linear expansion of the rotary shaft 120 satisfy a relationship described below. When temperature T0<temperature T1, the coefficient of linear expansion of the weight unit 112 is preferably smaller than the coefficient of linear expansion of the rotary shaft 120. In addition, when temperature T0>temperature T1, the coefficient of linear expansion of the weight unit 112 is preferably larger than the coefficient of linear expansion of the rotary shaft 120. Such a material section enables a state where the weight unit 112 and the rotary shaft 120 are joined stronger to be maintained in the actual operating step in which excitation light is provided to the target material. For example, when molten tin (Sn) is used as the target material, since the actual operating step of providing the target material with excitation light is to be performed at a relatively high temperature, the coefficient of linear expansion of the weight unit 112 is preferably smaller than the coefficient of linear expansion of the rotary shaft 120. In addition, when frozen xenon (Xe) is used as the target material, since the actual operating step of providing the target material with excitation light is to be performed at a relatively low temperature, the coefficient of linear expansion of the weight unit 112 is preferably larger than the coefficient of linear expansion of the rotary shaft 120. Adopting such coefficients of linear expansion enable the joint between the weight unit 112 and the rotary shaft 120 to be made strong. Therefore, vibration during rotation of the target holding unit 110 can be suppressed and the irradiation position PS of the excitation light LR can be stabilized. Note that shrink-fitting refers to fitting the rotary shaft 120 into the hole of the weight unit 112 by raising the temperatures of the weight unit 112 and the rotary shaft 120, fitting the rotary shaft 120 into the hole of the weight unit 112 in an expanded state, and cooling the weight unit 112 and the rotary shaft 120 after fitting. In addition, cold fitting refers to fitting the rotary shaft 120 into the hole of the weight unit 112 by lowering the temperatures of the weight unit 112 and the rotary shaft 120, fitting the rotary shaft 120 into the hole of the weight unit 112 in a contracted state, and heating (or restoring temperatures of) the weight unit 112 and the rotary shaft 120 after fitting.

The weight unit 112 may be joined to the rotary shaft 120 by welding. In addition, the weight unit 112 may be fastened by a bolt to a flange provided on the rotary shaft 120. Adopting such a configuration enables the joint between the weight unit 112 and the rotary shaft 120 to be made strong.

The axial rotation drive unit 130 is an axial rotation drive source such as a motor, a gear, or the like that is connected to the rotary shaft 120 and provides the rotary shaft 120 with a rotational drive force. In other words, as shown in the embodiment, when an axial rotation drive source such as a motor is connected to the rotary shaft 120 and the motor provides the rotary shaft 120 with a drive force, the axial rotation drive unit is the axial rotation drive source that is the motor. Alternatively, when a gear is connected to the rotary shaft 120 and a drive force of a motor or the like connected to a rotary shaft that differs from the rotary shaft 120 is transmitted to the rotary shaft 120 via the gear, the axial rotation drive unit 130 is the gear connected to the rotary shaft 120.

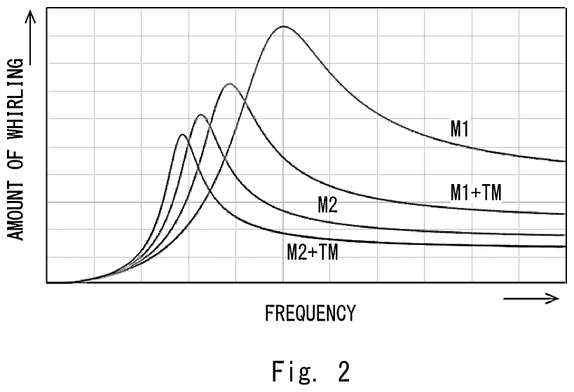

FIG. 2 is a graph illustrating an amount of whirling from the central axis C when the target holding unit 110 rotates around the central axis C in the light source apparatus 100 according to the first embodiment, in which an axis of abscissa indicates a frequency of rotation of the target holding unit 110 and an axis of ordinate indicates the amount of whirling. The axis of abscissa and the axis of ordinate respectively increase in arrow directions.

FIG. 2 shows, when a mass M of the target holding unit 110 is a mass M1 and a mass M2, respectively, a case where the target material TM is present (M1+TM and M2+TM) and a case where the target material TM is absent (M1 and M2). A relationship among the four masses of the mass M1, the mass M1+TM, the mass M2, and the mass M2+TM is expressed as mass M2+TM>mass M2>mass M1+TM>mass M1.

As shown in FIG. 2, the respective masses (mass M1, mass M1+TM, mass M2, and mass M2+TM) all have a frequency at which the amount of whirling peaks when the frequency is changed. A velocity (angular velocity) derived from the frequency at which the amount of whirling peaks is called a critical velocity (critical angular velocity) ωn=√(k/M). The greater the mass M, the lower the critical velocity ωn. In addition, when the frequency exceeds the critical velocity ωn, the greater the mass M, the smaller the amount of whirling. When the target material TM that is molten metal or the like is present, the critical velocity ωn decreases and the amount of whirling when the frequency exceeds the critical velocity ωn also decreases. This is conceivably due to a balancing effect of liquid. Although not illustrated, when the diameter of the rotary shaft 120 is reduced, the amount of whirling when the frequency exceeds the critical velocity ωn increases.

In the present embodiment, the target holding unit 110 has a mass M such that the critical angular velocity ωn during rotation is equal to or lower than 85% of a predetermined target rotational angular velocity ω0. The target rotational angular velocity ω0 is a target angular velocity at which the target holding unit 110 is to be rotated.

The mass M of the target holding unit 110 is a mass in a state where the target material TM is not fed to the target holding unit 110. The mass M of the target holding unit 110 may be a mass to which is added a mass of the target material TM in a state where the target material TM is fed in any of: an amount smaller than a predetermined target amount; a same amount as the predetermined target amount; and an amount equal to or larger than the predetermined target amount. Among these masses, by setting the mass M of the target holding unit 110 as a mass in a state where the target material TM is not fed, a total mass of the rotating body to which the target material TM has been fed from this state virtually increases due to a liquid amount of the target material TM. A rotational velocity that maximizes the amount of whirling is smaller than the critical angular velocity ωn=√(k/M) in a state where the target material TM is not fed and becomes even smaller than the predetermined target rotational angular velocity ω0, which is preferable.

Returning to FIG. 1, the rotary shaft 120 supports the target holding unit 110. For example, the rotary shaft 120 is a columnar rod shape that extends in the Z-axis direction and has the central axis C along the Z-axis direction. The rotary shaft 120 rotates around the central axis C due to a rotational drive force of the axial rotation drive unit 130. Accordingly, the rotary shaft 120 rotates the target holding unit 110. The coefficient of linear expansion of the rotary shaft 120 is larger than the coefficient of linear expansion of the weight unit 112. Therefore, when the rotary shaft 120 is shrink-fitted to the weight unit 112, the joint between the rotary shaft 120 and the weight unit 112 can be made strong.

The target holding unit 110 is rotated at the predetermined target rotational angular velocity ω0 via the rotary shaft. The rotary shaft 120 is rotated by the axial rotation drive unit 130 that is connected to the rotary shaft 120. For example, the axial rotation drive unit 130 is an axial rotation drive source such as a motor that is connected to the rotary shaft 120. Alternatively, the axial rotation drive unit 130 may be a power transmission mechanism such as a gear that is connected to the rotary shaft 120 and transmits, to the rotary shaft 120, a drive force from another rotary shaft connected to an axial rotation drive source such as a motor. The axial rotation drive unit 130 is connected to the rotary shaft 120 and rotates, via the rotary shaft 120, the target holding unit 110 around the central axis C of the rotary shaft 120. The axial rotation drive unit 130 rotates the target holding unit 110 at the predetermined target rotational angular velocity ω0.

The refill unit 140 refills the conveying unit 111 with molten metal so that a predetermined amount of the target material TM is held by the conveying unit 111. The refill unit 140 may supply the conveying unit 111 with the target material TM in a solid form, a liquid form, a gaseous form, a powder form, or the like or refill the target material TM by returning the target material TM adhered to a storage member such as a debris shield to the conveying unit 111. The mass of the weight unit 112 may be determined based on the mass of the conveying unit 111 and the mass of a predetermined amount of molten metal.

For example, the vacuum chamber 150 includes a housing, the interior of which is depressurized. For example, the vacuum chamber 150 is exhausted by a vacuum pump. The conveying unit 111 is arranged in the vacuum chamber 150. Note that the vacuum chamber 150 is not limited to the conveying unit 111 and another portion of the target holding unit 110 may be arranged therein and, in addition to the target holding unit 110, another member of the light source apparatus 100 such as the rotary shaft 120, the axial rotation drive unit 130, and the refill unit 140 may be arranged therein.

For example, the weight casing 160 includes a housing. At least a part of the weight unit 112 is arranged in the weight casing 160. For example, the cylindrical portion 112c of the weight unit 112 is arranged in the weight casing 160. Note that the columnar portion 112a and the disk portion 112b may be arranged in the weight casing 160. The cylindrical portion 112c of the weight unit 112 rotates around the central axis C inside the weight casing 160.

The cooling unit 170 is arranged between the conveying unit 111 and the weight unit 112 at a position in proximity to the conveying unit 111 and the columnar portion 112a. For example, the cooling unit 170 includes a heat sink. The cooling unit 170 cools the target holding unit 110. For example, the cooling unit 170 cools the target holding unit 110 using a cooling gas. Arranging the cooling unit 170 at such a position enables temperature control of the conveying unit 111 and the rotary shaft 120 to be readily performed and enables vibration of the target holding unit 110 to be suppressed. The cooling gas is a gas that is introduced in order to increase thermal conductivity between the cooling unit 170 such as a heat sink and the target holding unit 110 that is a cooling object.

An introduction port 162 is formed in the cooling unit 170. The introduction port 162 introduces the cooling gas to be used to cool the target holding unit 110 toward the conveying unit 111. The exhaust port 161 is formed in the weight casing 160. The exhaust port 161 exhausts the cooling gas having been used to cool the target holding unit 110. The exhaust port 161 may be provided at a position that opposes the cylindrical portion 112c in the weight casing 160. The cooling gas is introduced from the introduction port 162, passes through a space between the cooling unit 170 and the conveying unit 111, a space between the cooling unit 170 and the columnar portion 112a, and a space between the cooling unit 170 and the disk portion 112b, and is exhausted from the exhaust port 161 provided at a position opposing the cylindrical portion 112c. Due to the cooling gas following such a path, efficient temperature control of the target holding unit 110 can be performed.

The input optical system 180 irradiates the target material TM with the excitation light LR. The input optical system 180 may include a focusing lens 181. The input optical system 180 may include a laser that generates the excitation light LR and a mirror that reflects the excitation light LR. Note that the input optical system 180 is not limited to the focusing lens 181, a laser, a mirror, and the like and may include another optical member as long as the optical member irradiates the target material TM with the excitation light LR.

The input optical system 180 may irradiate the target material TM with the excitation light LR at an angle that is inclined with respect to a perpendicular axis to a surface of the target material TM. Specifically, the input optical system 180 irradiates the irradiation position PS with the excitation light SP at an angle of incidence that is inclined with respect to a surface of the irradiation position PS that is irradiated with the excitation light LR. In this manner, radiating the excitation light LR at an inclined angle enables an effect of debris with respect to optical members including a collector mirror 191 to be suppressed.

The output optical system 190 extracts, from the light source apparatus 100, light L0 generated by irradiating the target material TM with the excitation light LR. For example, the output optical system 190 includes the collector mirror 191. The output optical system 190 is not limited to the collector mirror 191 and may include an optical member that extracts the light L0 generated by irradiating the target material TM with the excitation light LR. In addition, the output optical system 190 may include a second collector mirror (not illustrated) that further reflects the light L0 having been reflected by the collector mirror 191.

The collector mirror 191 reflects the light L0 generated from the target material TM by being irradiated with the excitation light LR. For example, the collector mirror 191 reflects EUV light LE generated by the irradiation of the excitation light LR. In other words, the light L0 may include the EUV light LE. The EUV light LE is generated from plasma created when the target material TM is irradiated with the excitation light LR. The EUV light LE generated from plasma created in the target material TM is emitted to an optical apparatus such as an inspection apparatus as illumination light. Therefore, the illumination light includes the EUV light LE generated from the plasma.

### <Optical Apparatus>

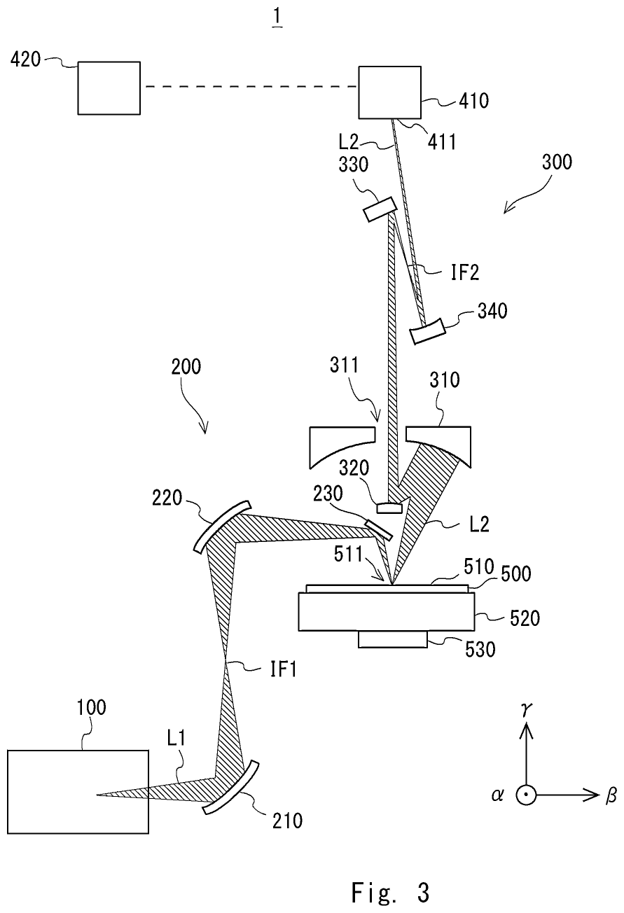

Next, an optical apparatus will be described. Hereinafter, a description will be given using an inspection apparatus as an example of an optical apparatus. FIG. 3 is a configuration diagram illustrating an inspection apparatus 1 including the light source apparatus 100 according to the first embodiment. As shown in FIG. 3, the inspection apparatus 1 includes an illuminating optical system 200, an inspecting optical system 300, a detector 410, and an image processing unit 420. Note that the inspection apparatus 1 may further include the light source apparatus 100. The inspection apparatus 1 is an apparatus that uses light L0 generated by the light source apparatus 100 as illumination light L1 to inspect a defect or the like of a sample 500. For example, the sample 500 is an EUV mask. Note that the sample 500 is not limited to an EUV mask and may be a semiconductor substrate or the like.

The illuminating optical system 200 includes a spheroidal mirror 210, a spheroidal mirror 220, and a drop-in mirror 230. The inspecting optical system 300 includes a holed concave mirror 310, a convex mirror 320, a plane mirror 330, and a concave mirror 340. The holed concave mirror 310 and the convex mirror 320 constitute a Schwarzschild magnifying optical system.

The light source apparatus 100 generates the illumination light L1. For example, the illumination light L1 includes EUV light LE of a same wavelength of 13.5 nm as an exposure wavelength of the EUV mask being the sample 500. Note that the illumination light L1 may include light other than EUV light. The illumination light L1 having been generated from the light source apparatus 100 is reflected by the spheroidal mirror 210. The illumination light L1 reflected by the spheroidal mirror 210 travels while being condensed and is focused on a convergence point IF1. Therefore, the spheroidal mirror 210 reflects the illumination light L1 having been generated from the light source apparatus 100 as convergent light. The convergence point IF1 is a position conjugate to an upper surface 510 of the sample 500 that is an EUV mask or the like and a detecting surface 411 of the detector 410.

After passing the convergence point IF1, the illumination light L1 travels while spreading and is incident to a reflective mirror such as the spheroidal mirror 220. Therefore, the illumination light L1 reflected by the spheroidal mirror 210 is incident via the convergence point IF1 to the spheroidal mirror 220 as divergent light. The illumination light L1 incident to the spheroidal mirror 220 is reflected by the spheroidal mirror 220, travels while being condensed, and is incident to the drop-in mirror 230. Therefore, the spheroidal mirror 220 reflects the incident illumination light L1 as convergent light. In addition, the spheroidal mirror 220 causes the illumination light L1 to be incident to the drop-in mirror 230. The drop-in mirror 230 is arranged directly above the EUV mask. The illumination light L1 incident to and reflected by the drop-in mirror 230 is incident to the sample 500. Therefore, the drop-in mirror 230 causes the illumination light L1 reflected by the spheroidal mirror 220 to be incident to the sample 500 by reflecting the illumination light L1 toward the sample 500.

The spheroidal mirror 220 focuses the illumination light L1 on the sample 500. The illuminating optical system 200 is installed such that an image of the light source apparatus 100 is formed on the upper surface 510 of the sample 500 when the illumination light L1 illuminates the sample 500. Therefore, the illuminating optical system 200 constitutes a critical illumination. In this manner, the illuminating optical system 200 illuminates the sample 500 that is an EUV mask or the like using the critical illumination due to the illumination light L1 generated by the light source apparatus 100.

The sample 500 is arranged on a stage 520. Here, let a plane parallel to the upper surface 510 of the sample 500 be an αβ plane and a direction perpendicular to the αβ plane be a γ-axis direction. The illumination light L1 is incident to the sample 500 in a direction inclined with respect to the γ-axis direction. In other words, the illumination light L1 is obliquely incident and illuminates the sample 500.

The stage 520 is a three-dimensionally driven stage that includes a drive unit 530. The drive unit 530 can cause a desired region of the sample 500 to be illuminated by moving the stage 520 within the αβ plane. Furthermore, the drive unit 530 can perform focus adjustment by moving the stage 520 in the γ-axis direction.

The illumination light L1 from the light source apparatus 100 illuminates an inspection region of the sample 500. The inspection region to be illuminated by the illumination light L1 is, for example, a 0.5 mm-square. Note that the inspection region is not limited to a 0.5 mm-square. The illumination light L1 is incident to the sample 500 in a direction inclined with respect to the γ-axis direction. Light from the sample 500 that is illuminated by the illumination light L1 is incident to the holed concave mirror 310. Hereinafter, the light from the sample 500 that is illuminated by the illumination light L1 will be described as reflected light L2. Light incident to the holed concave mirror 310 from the sample 500 is not limited to the reflected light L2 and may include diffracted light or the like. The reflected light L2 reflected by the sample 500 is incident to the holed concave mirror 310. A hole 311 is provided at a center of the holed concave mirror 310. The holed concave mirror 310 focuses the reflected light L2 from the sample 500 and reflects the focused reflected light L2 as convergent light.

The reflected light L2 reflected by the holed concave mirror 310 is incident to the convex mirror 320. The convex mirror 320 reflects, toward the hole 311 of the holed concave mirror 310, the reflected light L12 reflected by the holed concave mirror 310. The reflected light L2 having passed through the hole 311 is incident to the plane mirror 330. The plane mirror 330 causes the reflected light L2 reflected by the convex mirror 320 to be incident as convergent light through the hole 311 of the holed concave mirror 310. The reflected light L2 incident to the plane mirror 330 is reflected by the plane mirror 330. The reflected light L2 reflected by the plane mirror 330 travels while being condensed and is focused on a convergence point IF2. Therefore, the plane mirror 330 reflects the incident reflected light L2 as convergent light. The convergence point IF2 may sometimes be referred to as an aperture diaphragm. The convergence point IF2 is a position conjugate to the upper surface 510 of the sample 500 and the detecting surface 411 of the detector 410.

After passing the convergence point IF2, the reflected light L2 travels while spreading and is incident to the concave mirror 340. Therefore, the reflected light L2 reflected by the plane mirror 330 as convergent light is incident via the convergence point IF2 to the concave mirror 340 as divergent light. The concave mirror 340 reflects the incident reflected light L2 as convergent light toward the detector 410. The reflected light L2 reflected by the concave mirror 340 is detected by the detector 410. In this manner, the inspecting optical system 300 inspects the sample 500 that is an inspection object with light L1 extracted from the output optical system 190 of the light source apparatus 100. In other words, the inspecting optical system 300 focuses the reflected light L2 from the sample 500 illuminated by the illumination light L1 and guides the focused reflected light L2 to the detector 410.

The detector 410 may include a TDI (Time Delay Integration) sensor. The detector 410 receives light from the sample 500 illuminated by the illumination light L1. A region on the sample 500 that is detected by the detector 410 is referred to as a visual field region 511. The detector 410 receives reflected light L2 from the visual field region 511 illuminated by the illumination light L1. The visual field region 511 may be included in the inspection region illuminated by the illumination light L1. The detector 410 acquires image data of the sample 500 that is an EUV mask or the like. When the detector 410 includes a TDI sensor, the detector 410 includes a plurality of image capturing elements arranged in a line-shape in one direction. For example, the image capturing elements are CCDs (Charge Coupled Devices). Note that the image capturing elements are not limited to CCDs.

Image data of the sample 500 acquired by the detector 410 is outputted to the image processing unit 420 and processed by the image processing unit 420. For example, the image processing unit 420 may be an information processing apparatus such as a server apparatus or a personal computer.

The reflected light L2 includes information such as a defect or the like of the sample 500. Regular reflected light of the illumination light L1 incident to the sample 500 in a direction inclined with respect to the Z-axis direction is detected by the inspecting optical system 300. When a defect is present in the sample 500, the defect is observed as a dark image. Such an observation method is referred to as bright-field observation. Note that the inspection apparatus 1 may cause illumination light L1 to be incident to the sample 500 in the Z-axis direction and have the inspecting optical system 300 detect the illumination light L1. When a defect is present in the sample 500, the defect is observed as a bright image. Such an observation method is referred to as dark-field observation.

As described above, the inspection apparatus 1 according to the present embodiment includes the light source apparatus 100 described earlier and the inspecting optical system 300 that inspects an inspection object with light L0 extracted from the output optical system 190. While the inspection apparatus 1 has been described as an optical apparatus, the optical apparatus may be an exposure apparatus. For example, the exposure apparatus includes the light source apparatus 100 described earlier and an exposure optical system that exposes an exposure object with light L0 extracted from the output optical system 190.

Next, an advantageous effect of the present embodiment will be described. In the light source apparatus 100 according to the present embodiment, the target holding unit 110 includes the weight unit 112 on the side of the axial rotation drive unit 130. Therefore, rotation of the target holding unit 110 can be stabilized and stability of generated light L0 can be improved.

In addition, due to including the weight unit 112, the light source apparatus 100 can reduce an amount of whirling during rotation of the target holding unit 110. Accordingly, stability of the generated light L0 can be improved. For example, since the light source apparatus 100 includes the weight unit 112, the critical angular velocity ωn during rotation of the target holding unit 110 can be reduced and the amount of whirling during rotation of the target holding unit 110 can be reduced.

Furthermore, the target holding unit 110 has a mass such that the critical angular velocity ωn during rotation is equal to or lower than 85% of the target rotational angular velocity ω0. Therefore, the amount of whirling during rotation of the target holding unit 110 can be reduced. Accordingly, stability of the generated light L0 can be improved.

The rotary shaft 120 is shrink-fitted to the weight unit 112. For example, the coefficient of linear expansion of the rotary shaft 120 is set larger than the coefficient of linear expansion of the weight unit 112. Accordingly, a joint when the rotary shaft 120 is shrink-fitted to the weight unit 112 can be made strong and the amount of whirling during rotation of the target holding unit 110 can be reduced. Even when the temperature of the target holding unit 110 rises due to irradiation of the excitation light LR, adopting the relationship between coefficients of linear expansion described above enables the joint between the rotary shaft 120 and the target holding unit 110 to be made strong.

Furthermore, joining the weight unit 112 to the rotary shaft 120 by welding and fastening the weight unit 112 to a flange by a bolt enables the joint between the rotary shaft 120 and the weight unit 112 to be made stronger. Shrink-fitting, welding, and fastening by a bolt may be implemented independently or several of these methods may be implemented in combination.

The conveying unit 111 is detachable from the weight unit 112. Therefore, a test of balance of mass or the like of the weight unit 112 can be readily performed in a state where the conveying unit 111 is not attached to the weight unit 112. For example, an adjustment by the balance hole 114 can be more readily performed and an adjustment of the weight unit 112 can be refined.

The conveying unit 111 is attached to the weight unit 112 when providing the excitation light LR after passing the test of balance or the like of the weight unit 112. Therefore, an adjustment of the weight unit 112 by the balance hole 114 can be performed and a subsequent adjustment of the conveying unit 111 itself can be more readily performed. In this manner, the target holding unit 110 is capable of improving maintainability.

The refill unit 140 makes an adjustment so that a predetermined amount of the target material TM is held by the conveying unit 111. Therefore, rotation of the target holding unit 110 can be stabilized and vibration control can be improved.

The light source apparatus 100 includes the cooling unit 170 that is a heat sink or the like. For example, a decline in light source efficiency can be suppressed by exhausting a cooling gas from the exhaust port 161.

### Second Embodiment

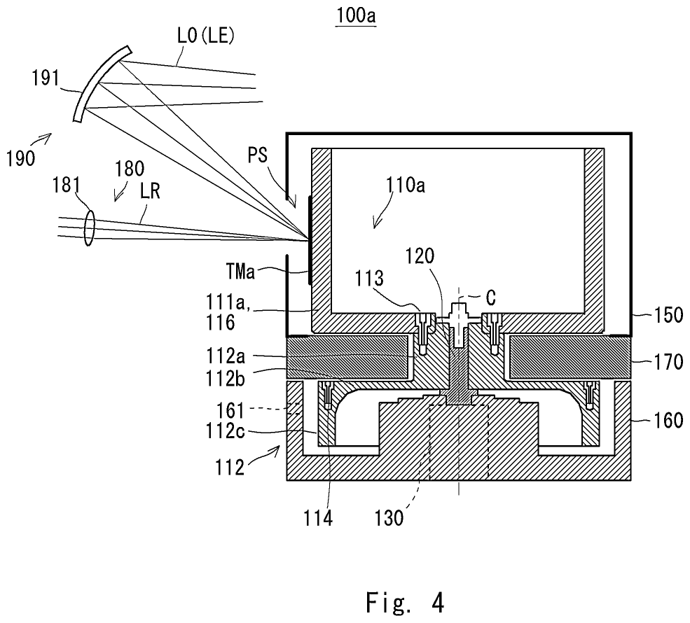

Next, a light source apparatus according to a second embodiment will be described. In the light source apparatus according to the present embodiment, the target holding unit includes a drum. FIG. 4 is a sectional view illustrating a light source apparatus 100a according to the second embodiment. As shown in FIG. 4, in the light source apparatus 100a according to the present embodiment, a target holding unit 110a includes a drum 116 as a conveying unit 111a.

The drum 116 has a cylindrical shape (cylinder shape) and fixes a target material TMa such as xenon (Xe) to an outer surface of a cylindrical part by freezing the target material TMa as a solid material. The input optical system 180 irradiates the outer surface of the cylindrical part of the drum 116 with the excitation light LR. In this manner, the target holding unit 110a according to the present embodiment holds the target material TMa that generates light L0 when the excitation light LR is provided.

According to the present embodiment, even when the light source apparatus 100a includes the conveying unit 111a that is the drum 116 or the like, vibration during rotation of the target holding unit 110a can be suppressed and stability of the generated light L0 can be improved. Other configurations and advantageous effects are included in the description of the first embodiment.

While embodiments of the present disclosure have been described above, the present disclosure includes appropriate modifications that do not impair its purpose and advantages and, further, the present disclosure is not limited by the above embodiments. In addition, combinations of the respective configurations of the first and second embodiments are also within the scope of the technical concepts of the present disclosure.

The first and second embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A light source apparatus, comprising:
a target holding unit including a holding region configured to hold a target material that generates light by excitation light being provided;
a rotary shaft configured to support the target holding unit; and
an axial rotation drive unit that is connected to the rotary shaft and configured to rotate the target holding unit around a central axis of the rotary shaft, wherein
the target holding unit is rotated by a predetermined target rotational angular velocity, and
the target holding unit has a mass such that a critical angular velocity during rotation is equal to or lower than 85% of the target rotational angular velocity.

2. The light source apparatus according to claim 1, wherein
the target holding unit includes the holding region and a weight unit,
when one orientation in a direction of the central axis is considered one side and an orientation on an opposite side to the one side is considered another side,
the holding region is arranged on the one side of the weight unit, and
the weight unit extends on the other side.

3. A light source apparatus, comprising:
a target holding unit including a holding region configured to hold a target material that generates light by excitation light being provided;
a rotary shaft configured to support the target holding unit; and
an axial rotation drive unit that is connected to the rotary shaft and configured to rotate the target holding unit around a central axis of the rotary shaft, wherein
the target holding unit includes the holding region and a weight unit,
when one orientation in a direction of the central axis is considered one side and an orientation on an opposite side to the one side is considered another side,
the holding region is arranged on the one side of the weight unit, and
the weight unit extends on the other side.

4. The light source apparatus according to claim 1, wherein
the target holding unit includes:
a conveying unit configured to hold the target material with the holding region and convey the target material to an irradiation position; and
a weight unit joined to the rotary shaft, wherein
the conveying unit is detachable from the weight unit and is attached to the weight unit when the excitation light is provided to the target material.

5. The light source apparatus according to claim 2, wherein
a temperature during a step of fitting the rotary shaft into the weight unit is lower than a temperature of the rotary shaft and the weight unit when providing the target material with the excitation light and, at the same time, a coefficient of linear expansion of the weight unit is smaller than the coefficient of linear expansion of the rotary shaft, or a temperature during the step of fitting the rotary shaft into the weight unit is higher than a temperature of the rotary shaft and the weight unit when providing the target material with the excitation light and, at the same time, a coefficient of linear expansion of the weight unit is larger than the coefficient of linear expansion of the rotary shaft.

6. The light source apparatus according to claim 2, wherein
the target material is molten tin and, at the same time, a coefficient of linear expansion of the weight unit is smaller than the coefficient of linear expansion of the rotary shaft, or the target material is frozen xenon and, at the same time, a coefficient of linear expansion of the weight unit is larger than the coefficient of linear expansion of the rotary shaft.

7. The light source apparatus according to claim 2, wherein
the weight unit is joined to the rotary shaft by welding.

8. The light source apparatus according to claim 2, wherein
the weight unit is fastened by a bolt to a flange provided on the rotary shaft.

9. The light source apparatus according to claim 4, wherein
the target material is molten metal, and
the conveying unit is configured to hold the target material with a centrifugal force created by a rotation around the central axis and convey the target material to the irradiation position.

10. The light source apparatus according to claim 4, wherein
the target holding unit further includes a joining member configured to join the conveying unit and the weight unit,
the joining member is attached from the conveying unit toward the weight unit,
the conveying unit rotates together with the weight unit when joined to the weight unit by the joining member, and
the conveying unit is detachable from the rotary shaft when not joined by the joining member.

11. The light source apparatus according to claim 10, wherein
the weight unit includes a hole-shaped balance hole configured to adjust a balance of mass of the weight unit, and
the conveying unit is attached to the weight unit after passing a test in a state where the conveying unit is not attached to the weight unit.

12. The light source apparatus according to claim 9, further comprising
a refill unit configured to refill the conveying unit with the molten metal so that a predetermined amount of the target material is held by the conveying unit, and
a mass of the weight unit is determined based on the mass of the conveying unit and the mass of the predetermined amount of the molten metal.

13. The light source apparatus according to claim 4, further comprising:
a vacuum chamber in which the conveying unit is arranged;
a weight casing in which at least a part of the weight unit is arranged; and
a cooling unit that is arranged between the conveying unit and the weight unit and configured to cool the target holding unit.

14. The light source apparatus according to claim 13, further comprising:
an introduction port that is formed in the cooling unit and configured to introduce a cooling gas toward a space between the cooling unit and the conveying unit; and
an exhaust port that is formed in the weight casing and configured to exhaust the cooling gas.

15. An optical apparatus, comprising
the light source apparatus according to claim 1,
the optical apparatus performing lithography or an inspection based on light generated from the target material.
